(19) United States
(12) Patent Application Publication
(10) Pub. No.: US 2009/0311516 A1
(43) Pub. Date: Dec. 17, 2009

(54) TI-BASED COMPOSITE MATERIAL AND METHOD FOR MAKING THE SAME

(75) Inventor: PAI-SHENG WEI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Foxconn Technology Co., Ltd., Tu-Cheng (TW)

(21) Appl. No.: 12/411,413

(22) Filed: Mar. 26, 2009

(30) Foreign Application Priority Data
Jun. 13, 2008 (CN) 200810067743.5

(51) Int. Cl. B32B 15/04; C23C 14/34

(52) U.S. Cl. 428/335; 428/472; 205/190

(57) ABSTRACT

A method for making a Ti-based composite material, comprising steps of: providing a Ti-based block; forming an aluminum layer on the Ti-based block; anodizing the aluminum layer to form a transparent aluminum oxide film; and continuing the anodizing process to form a titanium oxide film between the aluminum oxide film and the Ti-based block. Thus the aluminum oxide film is located at an outmost side of the Ti-base composite material for protecting the composite material from contamination. The titanium oxide film is located between the Ti-based block and the aluminum oxide film for enhancing an aesthetic feeling of products made of the Ti-based composite materials.

### BACKGROUND

1. Technical Field

The disclosure generally relates to Ti-based composite materials, and more particularly to a method for making the Ti-based composite materials.

2. Description of Related Art

Ti-based materials, including Ti and Ti-alloy, are widely used for their excellent properties, such as high specific strength and high hardness. A titanium oxide layer is usually formed on an outer surface of the Ti-based material for enhancing an aesthetic feeling of products made of the Ti-based material since a color of the titanium oxide layer can be various according to a thickness of the titanium oxide layer, such as golden, red, blue, green, purple, etc. However, pores of the titanium oxide layer are relatively large, and thus contaminations, such as finger mark and dust, are easily adhered to the titanium oxide layer. Thus after a period of time, the Ti-based products will lose their shining property and look obsolete.

For the foregoing reasons, there is a need in the art for a Ti-based composite material and a method for making the same to overcome the limitations described.

### BRIEF DESCRIPTION OF THE DRAWINGS

FIG. 1 is a flowchart of a method of making a Ti-based composite material according to an exemplary embodiment.

FIG. 2 is a cross sectional view showing an aluminum layer formed on a Ti-based block.

FIG. 3 is a cross sectional view showing an aluminum oxide layer with a plurality of pores formed on the Ti-based block.

FIG. 4 is a cross sectional view showing a titanium oxide layer formed between the Ti-based block and the aluminum oxide layer.

FIG. 5 is a cross sectional view showing the Ti-based composite material formed by sealing the pores of the aluminum oxide layer.

### DETAILED DESCRIPTION

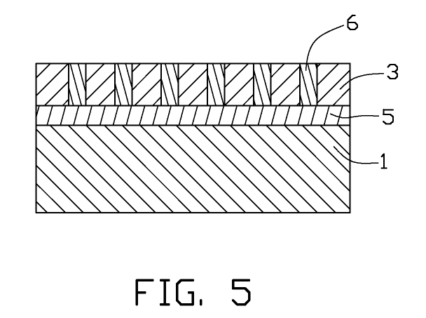

Referring to FIG. 5, a Ti-based composite material according to an exemplary embodiment includes a Ti-based block 1, a titanium oxide layer 5 directly and integrally formed on the Ti-based block 1, and a transparent aluminum oxide layer 3 directly and integrally formed on the titanium oxide layer 5. In other words, the aluminum oxide layer 3 is at an outmost side of the Ti-based composite material, and the titanium oxide layer 5 is located between the aluminum oxide layer 3 and the Ti-based block 1.

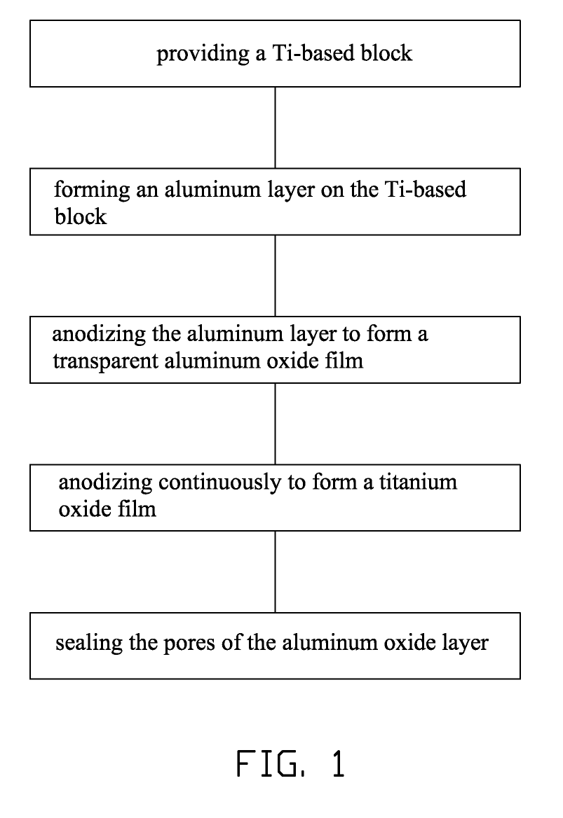

Referring to FIGS. 1-4 also, a method for making the Ti-based composite material includes the following steps: a) providing the Ti-based block 1; b) forming the aluminum layer 2 on the Ti-based block 1; c) anodizing the aluminum layer 2 to form the aluminum oxide film 3 with a plurality of pores 4; d) continuing the anodizing process to form the titanium oxide film 5 between the aluminum oxide film 3 and the Ti-based block 1; and e) sealing the pores 4 of the aluminum oxide film 3 to form the Ti-based composite material. Details are given below.

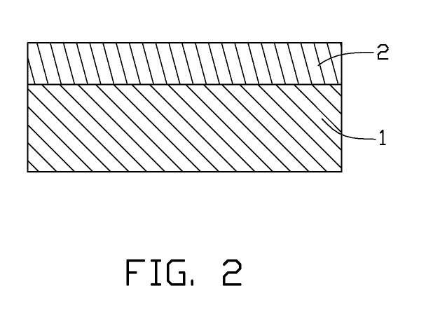

Firstly, the Ti-based block 1 is provided. The Ti-based block 1 can be Ti or Ti-alloy. Although the illustrated Ti-based block 1 takes the form of a rectangular block, it may take the form of rods or cylinders. The Ti-based block 1 forms a planar top surface. Referring to FIG. 2, the aluminum layer 2 is then directly coated on the top surface of the Ti-based block 1 through vacuum sputtering or vaporization. The top surface of the Ti-based block 1 is processed with degreasing, caustic scrubbing, neutralizing, and cleaning before forming the aluminum layer 2 thereon so that aluminum layer 2 can be firmly attached to the top surface of the Ti-based block 1.

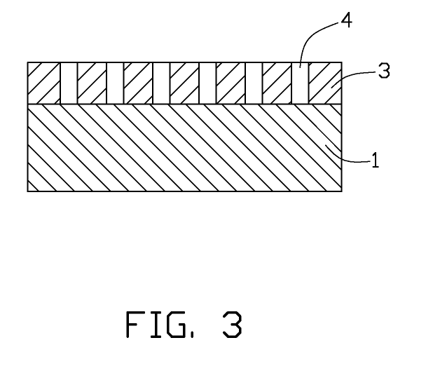

Referring to FIG. 3, the aluminum layer 2 is then anodized to form an aluminum oxide film 3 on the top surface of the Ti-based block 1. Preferably, the aluminum oxide film 3 is transparent. For the anodic oxidation treatment, an electrolyte including sulfuric acid, phosphoric acid, chromic acid, or organic acid, is provided. The aluminum layer 2 formed on the Ti-based block 1 functions as an anode, and a platinum sheet is provided and functions as a cathode. A power source supplies a current to the Ti-based block 1. The power source can be adjusted to change a current density flowing through the Ti-based block 1. During the anodic oxidation treatment, the current density, a temperature of the electrolyte, and an acid concentration of the electrolyte may influence a property of the aluminum oxide film 3, such as a thickness, a color, and a pore formation capability of the aluminum oxide film 3.

Preferably, in this anodic oxidation treatment, the electrolyte is a sulfuric acid solution with a concentration in range of 10-20 wt % and a temperature in range of 293-303K. A voltage of the power source is in range of 10-20V, and a current density through the aluminum layer 2 is about 1-2 A/dm². After about 10-30 minutes, the aluminum oxide film 3 is formed on the Ti-based block 1 with a thickness about 5-30 μm. The aluminum oxide film 3 is transparent, and forms a plurality of micro-pores 4 therein.

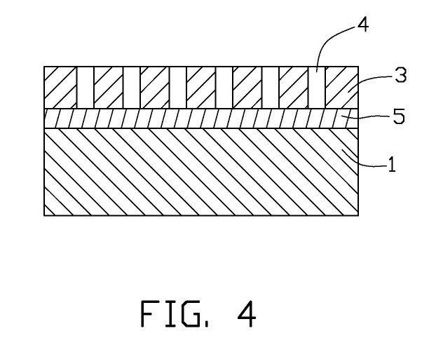

Referring to FIG. 4, after the aluminum layer 2 is anodized completely, the electrolyte contacts with the top surface of the Ti-based block 1 through the micro-pores 4 formed in the aluminum oxide film 3. Then anodizing process is proceeded continuously to form the titanium oxide film 5 at the top surface of the Ti-based block 1, i.e., between the Ti-based block 1 and the aluminum oxide film 3. A thickness of the titanium oxide film 5 is decided by the voltage of the power source, and the titanium oxide film 5 with different thickness has different color. In other words, the color of the titanium oxide film 5 is decided by the anodizing voltage. For example, a yellow titanium oxide film 5 is formed when the voltage is 5V, and a purple titanium oxide film 5 is formed when the voltage is 15V

Referring to FIG. 5, finally, the micro-pores 4 are sealed to form the Ti-based composite material. A method for sealing the micro-pores 4 can be hydration sealing, inorganic salt solutions sealing, or lacquer film sealing. For example, in the hydration sealing, the Ti-based block 1 with the aluminum oxide film 3 and the titanium oxide film 5 is immersed into pure water of about 353K. The aluminum oxide film 3 generates hydration reaction with the water to form hydrate 6 which is a solid compound containing water molecules. The hydrate 6 has a density less than that of the aluminum oxide, and thus has a volume larger than that of the aluminum oxide and expands into the micro-pores 4 of the aluminum oxide film 3 to seal the micro-pores 4. Thus the contaminations can not adhere to the Ti-based composite material easily since the aluminum oxide film 3 with sealed micro-pores 4 is formed on the outmost side of the Ti-based composite material. Even after using a long period of time, the materials look like new. In addition, as the aluminum oxide film 3 on the titanium oxide film 5 is transparent, the color of the Ti-based composite material is the color of the titanium oxide film 5. Therefore, the Ti-based composite materials can have different colors by adjusting the anodizing voltage.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A Ti-based composite material, comprising:
a Ti-based block;
a titanium oxide layer directly and integrally formed on the Ti-based block; and
an aluminum oxide layer directly and integrally formed on the titanium oxide layer.

2. The Ti-based composite material of claim 1, wherein the aluminum oxide layer is transparent.

3. The Ti-based composite material of claim 1, wherein the aluminum oxide layer has a thickness in a range of 5-30 μm.

4. The Ti-based composite material of claim 1, wherein the Ti-based block is Ti or Ti-alloy.

5. A method for making a Ti-based composite material, comprising steps of:
providing a Ti-based block;
forming an aluminum layer on the Ti-based block;
anodizing the aluminum layer to form a transparent aluminum oxide film; and
continuing the anodizing process to form a titanium oxide film between the aluminum oxide film and the Ti-based block.

6. The method of claim 5, wherein a plurality of micro-pores are formed in the aluminum oxide film during the step of anodizing the aluminum layer, and the micro-pores are sealed after forming the titanium oxide film.

7. The method of claim 6, wherein a method for sealing the micro-pores is one of hydration sealing, inorganic salt solutions sealing, and lacquer film sealing.

8. The method of claim 6, wherein the aluminum layer is coated on the Ti-based block through vacuum sputtering or vaporization.

9. The method of claim 6, wherein the aluminum oxide film is formed by anodizing the aluminum layer for 10-30 minutes in a sulfuric acid solution with a concentration in a range of 10-20 wt % and a temperature in a range of 293-303K.

10. The method of claim 9, wherein an anodizing voltage is in a range of 10-20V, and a current density through the aluminum layer is 1-2 A/dm².

11. The method of claim 10, wherein the aluminum oxide film has a thickness in a range of 5-30 μm.

12. The method of claim 5, wherein the Ti-based block is Ti or Ti-alloy.
